(19) United States
(12) Patent Application Publication
(10) Pub. No.: US 2026/0042630 A1
(43) Pub. Date: Feb. 12, 2026

(54) TAPE RELEASING DEVICE AND TAPE LOADING DEVICE

(71) Applicant: FUJI CORPORATION, Chiryu (JP)

(72) Inventor: Mizuho NOZAWA, Kota-cho (JP)

(73) Assignee: FUJI CORPORATION, Chiryu (JP)

(21) Appl. No.: 18/863,154

(22) PCT Filed: May 31, 2022
(86) PCT No.: PCT/JP2022/022124

§ 371 Date: Nov. 5, 2024

(51) Int. Cl. B65H 19/10; B65H 19/12

(52) U.S. Cl. CPC B65H 19/105; B65H 19/12; B65H 2301/3251; B65H 2405/461; B65H 2405/55

(57) ABSTRACT

A tape releasing device includes a reel support section and a release section. The reel support section is configured to support a reel in which an outer peripheral portion of a spiral tape, where a carrier tape, in which a cover tape that closes an accommodation section that accommodates an electronic component is attached to a base tape provided with the accommodation section, is spirally wound, and a tip end portion of the cover tape are fixed by a fixing tape. The release section releases the fixing tape of the reel supported by the reel support section.

### TECHNICAL FIELD

The present description herein discloses techniques related to a tape releasing device and a tape loading device.

### BACKGROUND ART

A pre-use component tape recognition section described in Patent Literature 1 performs image processing on an imaging result of a component reel and recognizes a tip end portion of a pre-use tape stored in the component reel. Further, a component tape setting processing section described in Patent Literature 1 causes a robot section and a pre-use tape holding tool based on a recognition result of the pre-use component tape recognition section to hold the tip end portion of the pre-use tape. Specifically, the tip end portion of the pre-use tape is gripped and held by a clip portion in the pre-use tape holding section.

An automatic tape processing apparatus disclosed in Patent Literature 2 processes so that a tip end of a top tape of a component packaging tape wound around a tape reel protrudes by a predetermined protrusion length from a tip end of a carrier tape. In the automatic tape processing apparatus disclosed in Patent Literature 2, a worker inserts the tip end portion of the component packaging tape into a tape entrance.

### Patent Literature

Patent Literature 1: JP 2019-204858 A

Patent Literature 2: WO 2014/097473

### BRIEF SUMMARY

### Technical Problem

A carrier tape is spirally wound on a reel. A tip end side of the carrier tape can be fixed to an outer peripheral portion of the spiral tape by a fixing tape. When the reel in which the tip end side of the carrier tape is fixed by the fixing tape is set in a feeder, it is necessary to release the fixing tape. When a worker performs the release of the fixing tape, the number of work steps of the worker increases.

In view of such circumstances, the present description herein discloses a tape releasing device and a tape loading device capable of releasing a fixing tape of a reel.

### Solution to Problem

The present description herein discloses a tape releasing device including a reel support section and a release section. The reel support section is configured to support a reel in which an outer peripheral portion of a spiral tape, where a carrier tape, in which a cover tape that closes an accommodation section that accommodates an electronic component is attached to a base tape provided with the accommodation section, is spirally wound, and a tip end portion of the cover tape are fixed by a fixing tape. The release section is configured to release the fixing tape of the reel supported by the reel support section.

The present description herein discloses a tape loading device including the tape releasing device described above and a loading section. The loading section is configured to load the carrier tape of the spiral tape, from which the fixing tape has been released, to a feeder configured to supply the electronic component to a collection position.

### Advantageous Effects

With the above tape releasing device, the fixing tape of the reel can be released. The tape loading device includes the tape releasing device. Therefore, what has been described above with respect to the tape releasing device can be said to be the same for the tape loading device.

### BRIEF DESCRIPTION OF DRAWINGS

FIG. 1 is a perspective view illustrating an example of a setup device.

FIG. 2 is a plan view of the setup device in FIG. 1.

FIG. 3 is a perspective view illustrating an example of a feeder provided in a feeder holding section.

FIG. 4 is a plan view illustrating an example of a carrier tape.

FIG. 5 is a cross-sectional view of the carrier tape in FIG. 4.

FIG. 6 is a flowchart illustrating an example of a control procedure by the setup device.

FIG. 7 is a schematic view illustrating an example of a tip end portion of the carrier tape.

FIG. 8 is a perspective view illustrating an example of a tape releasing device.

FIG. 9 is a flowchart illustrating an example of a control procedure by the tape releasing device.

FIG. 10 is a perspective view illustrating an example of a reel support section.

FIG. 11 is a side view of the reel support section in FIG. 10.

FIG. 12 is a plan view illustrating an example of a rear surface of a reel.

FIG. 13 is a perspective view illustrating an example of a gripping mechanism.

FIG. 14 is a transparent view of the reel illustrating an example of a state in which a first claw portion has reached an outer peripheral portion of a spiral tape.

FIG. 15 is a schematic view illustrating a positional relationship between the spiral tape in FIG. 14, and the gripping mechanism and a detection section.

FIG. 16 is a schematic view illustrating a state in which the first claw portion has reached an adhesive portion of the fixing tape.

FIG. 17 is a schematic view illustrating an example of an operation of a second claw portion.

FIG. 18 is a schematic view illustrating an example of a state in which a non-adhesive portion of the fixing tape is gripped.

FIG. 19 is a schematic view illustrating a movement of the gripping mechanism by a separation mechanism.

### DESCRIPTION OF EMBODIMENTS

### 1. Embodiments

### 1-1. Configuration Example of Setup Device 10

For example, tape releasing device 80 and tape loading device 100 can be applied to setup device 10. Setup device 10 sets reel 70 on feeder 60 so that electronic component 91 can be supplied from feeder 60. Setup device 10 need only automatically set reel 70 on feeder 60, and may take various configurations.

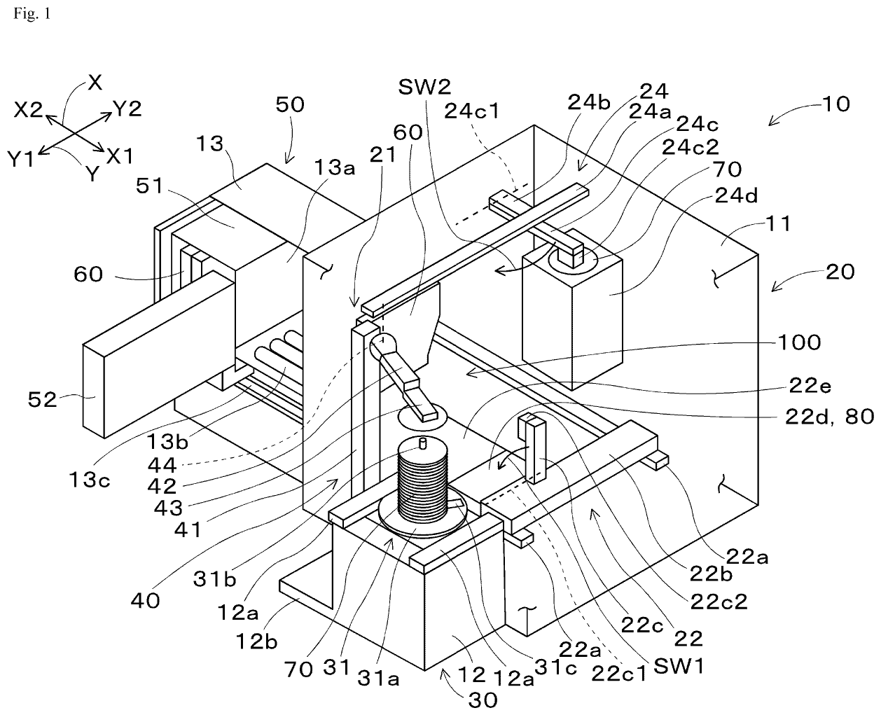

As illustrated in FIGS. 1 to 3, setup device 10 of an embodiment includes reel attachment/detachment section 20, reel supply section 30, reel transfer mechanism 40, and feeder supply section 50. For convenience of description, in the drawings, a facing direction of feeder 60 and reel 70 when reel 70 is attached to and detached from feeder 60 is referred to as a first direction (arrow X direction). In the first direction (arrow X direction), a direction (side) from feeder 60 toward reel 70 is referred to as a first end side (arrow X1 direction) in the first direction, and a direction (side) from reel 70 toward feeder 60 is referred to as a second end side (arrow X2 direction) in the first direction.

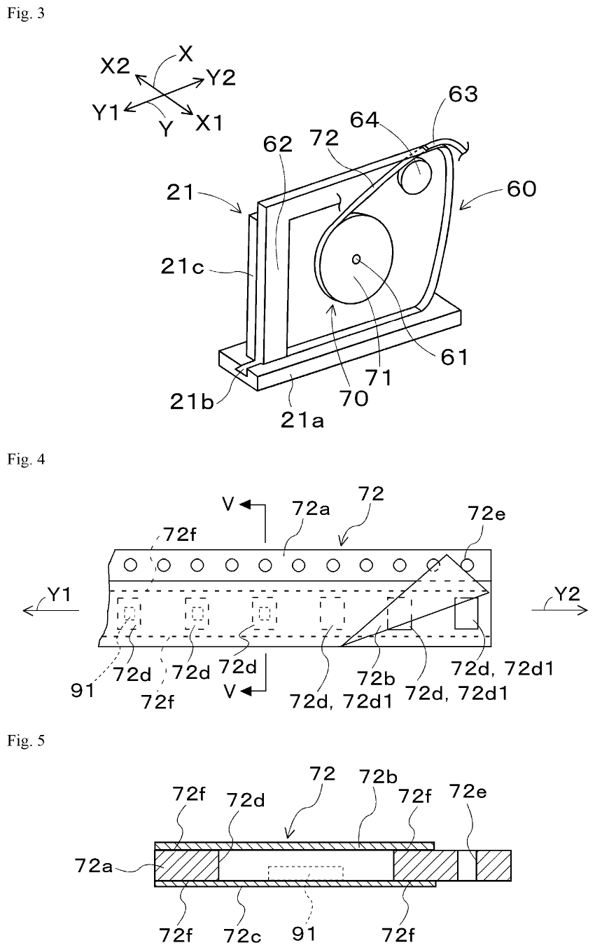

Further, as illustrated in FIG. 3, a sliding direction of feeder 60 in slot 21b, which is a direction orthogonal to the first direction (arrow X direction) in a horizontal plane, is referred to as a second direction (arrow Y direction). In the second direction (arrow Y direction), a sliding direction (side) when feeder 60 is detached is referred to as a first end side (arrow Y1 direction) in the second direction, and a sliding direction (side) when feeder 60 is attached is referred to as a second end side (arrow Y2 direction) in the second direction.

In reel attachment/detachment section 20, various members are assembled inside first housing 11. First housing 11 is a case having a rectangular parallelepiped shape, and a second end side (arrow X2 direction) in the first direction and a first end side (arrow Y1 direction) in the second direction are partially opened. Reel supply section 30 is provided to be coupled to a first end side (arrow Y1 direction) in the second direction of reel attachment/detachment section 20. Reel supply section 30 is formed in box-shaped base 12 smaller than first housing 11. Reel transfer mechanism 40 is provided on plate base 12b extending from a bottom portion of base 12 to a second end side (arrow X2 direction) in the first direction. Feeder supply section 50 is provided to be coupled to the second end side (arrow X2 direction) in the first direction of reel attachment/detachment section 20. In feeder supply section 50, various members are assembled inside second housing 13 which is smaller than first housing 11 and has storage space 13a in an upper portion.

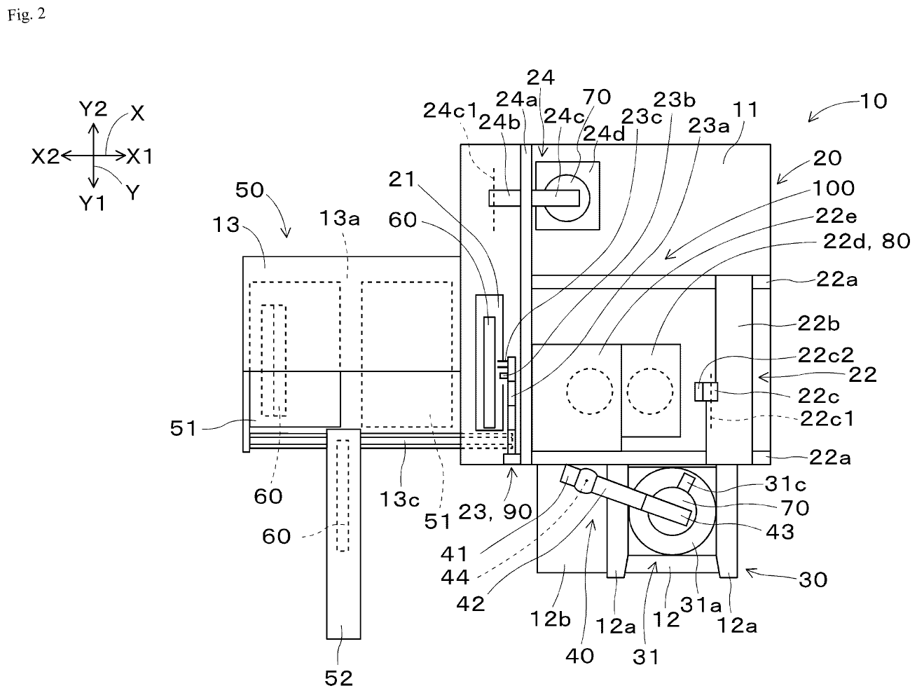

Reel attachment/detachment section 20 includes feeder holding section 21, reel attachment mechanism 22, tape loading mechanism 23, and reel detachment mechanism 24. As illustrated in FIG. 2, feeder holding section 21 is disposed on the second end side (arrow X2 direction) in the first direction and first end side (arrow Y1 direction) in the second direction inside first housing 11. Feeder holding section 21 holds feeder 60 at a work execution position in a vertical posture. As illustrated in FIG. 3, feeder holding section 21 includes bottom plate 21a, slot 21b, and support plate 21c. Slot 21b is formed in a groove shape extending along the second direction (arrow Y direction) in bottom plate 21a. Feeder 60 is inserted from a first end side (arrow Y1 direction) in the second direction of slot 21b toward the second end side (arrow Y2 direction) in the second direction thereof, and is held at the work execution position. Support plate 21c is provided to stand up from bottom plate 21a, and comes into contact with the side surface of feeder 60 at the work execution position on a second end side (arrow X2 direction) in the first direction. Support plate 21c supports a pressing load to the second end side (arrow X2 direction) in the first direction generated when reel 70 is attached to feeder 60.

Feeder 60 is detachably provided on a component mounter. As illustrated in FIG. 3, in feeder 60, reel 70, on which carrier tape 72 is wound, is attached to main body portion 71, and carrier tape 72 is conveyed to supply electronic component 91. An identification code for identifying reel 70 is given to each reel 70. Feeder 60 is formed in a flat box shape. Feeder 60 includes reel holding shaft 61 that protrudes from a side plate at the second end side (arrow X2 direction) in the first direction toward the first end side (arrow X1 direction) in the first direction at a substantially central position as viewed in the first direction (arrow X direction). Reel holding shaft 61 is inserted into a center hole formed at the center of reel 70, and detachably and rotatably holds reel 70.

As illustrated in FIGS. 4 and 5, carrier tape 72 includes base tape 72a, cover tape 72b, and bottom tape 72c. Base tape 72a is a base portion of carrier tape 72, and is provided with multiple accommodation sections 72d and multiple feed holes 72e. Electronic component 91 is accommodated in each of multiple accommodation sections 72d. As illustrated in FIG. 4, a predetermined number (for example, three in FIG. 4) of accommodation sections 72d from a tip end side of carrier tape 72 are empty accommodation sections 72d1 in which electronic component 91 is not accommodated. Multiple accommodation sections 72d are provided at predetermined pitch intervals in a longitudinal direction of carrier tape 72 at the center portion in a width direction of base tape 72a.

Each of multiple feed holes 72e is a through hole, and is used when carrier tape 72 is conveyed in the conveyance direction (the second end side (arrow Y2 direction) in the second direction). Multiple feed holes 72e are provided at a predetermined pitch interval in the longitudinal direction of carrier tape 72 on the first end side in the width direction of base tape 72a. Cover tape 72b closes accommodation sections 72d of base tape 72a. Cover tape 72b is attached to the upper surfaces of both end portions of base tape 72a in the width direction by, for example, adhesive 72f or thermocompression bonding. Bottom tape 72c is attached to the lower surface of base tape 72a by, for example, adhesive 72f or thermocompression bonding, and prevents electronic component 91 accommodated in accommodation section 72d from falling off.

A central portion of side plate 62 on a first end side (arrow X1 direction) in the first direction of feeder 60 is open in order to facilitate attachment and detachment of reel 70. At least one of the material of carrier tape 72, the width dimension of carrier tape 72, and the width dimension of reel 70 is different among multiple types of reels 70, and there are multiple types of feeders 60 corresponding to multiple types of reels 70. Feeder 60 includes collection position 63, sprocket 64, and a tape release section.

Collection position 63 is provided on a second end side (arrow Y2 direction) in the second direction of the upper surface of feeder 60, and the component mounter collects electronic component 91 at collection position 63. Sprocket 64 is rotatably provided on a first end side (arrow Y1 direction) in the second direction with respect to collection position 63. A teeth portion of sprocket 64 engage with feed hole 72e of carrier tape 72. Sprocket 64 is intermittently driven by a drive motor and conveys carrier tape 72 at a constant pitch. The tape release section can release cover tape 72b from base tape 72a immediately before collection position 63 to take out electronic component 91. After passing through collection position 63, carrier tape 72 is cut by a tape cutting device provided in the component mounter.

An identification code for identifying feeder 60 is given to each of feeders 60. Feeder 60 is provided with a feeder control section. The feeder control section stores the identification code of feeder 60 and the identification code of reel 70, and controls the component supply operation. When feeder 60 is held by feeder holding section 21, the connectors are fitted to each other, and the feeder control section is communicably connected to setup device 10.

Reel attachment mechanism 22 is provided on a first end side (arrow X1 direction) in the first direction of feeder holding section 21. Reel attachment mechanism 22 uses reel transfer mechanism 40 to change reel 70 from a horizontal posture to a vertical posture and attach reel 70 to feeder 60 at the work execution position. Reel attachment mechanism 22 includes pair of guide rails 22a and 22a, moving table 22b, attachment material 22c, placement area 22d, and temporary placement area 22e. Reel attachment mechanism 22 may be configured such that a mechanism that changes reel 70 from the horizontal posture to the vertical posture and a mechanism that attaches reel 70 in the vertical posture to feeder 60 are separated.

Pair of guide rails 22a and 22a extends along the first direction (arrow X direction) at a substantially central position in the second direction (arrow Y direction) of first housing 11, and is disposed in parallel to be separated from each other. Moving table 22b extends along the second direction (arrow Y direction), and is provided to straddle the upper side of pair of guide rails 22a and 22a. As illustrated in FIGS. 1 and 2, moving table 22b moves along pair of guide rails 22a and 22a, and reciprocates between a standby position provided on the first end side (arrow X1 direction) in the first direction and feeder holding section 21 provided on the second end side (arrow X2 direction) in the first direction.

Attachment material 22c is formed in a square bar shape, and is provided to extend upward from moving table 22b. Attachment material 22c faces reel holding shaft 61 of feeder 60 at the work execution position. Specifically, attachment material 22c is provided at a position separated by a predetermined distance from a tip end portion of reel holding shaft 61 toward the first end side (arrow X1 direction) in the first direction. Attachment material 22c swings (arrow SW1 in FIG. 1) between an upright posture illustrated in FIGS. 1 and 2 and a horizontal posture in which attachment material 22c is tilted toward the second end side (arrow X2 direction) in the first direction around swing shaft 22c1 provided on moving table 22b side. Collection section 22c2 is provided on an end portion on a side different from an end portion of swing shaft 22c1 side of attachment material 22c. Collection section 22c2 detachably collects reel 70. As collection section 22c2, a claw portion inserted into the center hole of reel 70, a gripping mechanism that grips a peripheral edge of reel 70, a pickup mechanism that picks up reel 70 using negative pressure, or the like may be used.

Placement area 22d is provided on the first end side (arrow X1 direction) in the first direction in pair of guide rails 22a and 22a. In placement area 22d, reel 70 to be attached is placed in a horizontal posture. Temporary placement area 22e is provided on pair of guide rails 22a and 22a on the second end side (arrow X2 direction) in the first direction with respect to placement area 22d. In temporary placement area 22e, when reel attachment mechanism 22 changes the use order of reels 70, reels 70 are temporarily placed in the horizontal posture and the use order of reels 70 is changed. In temporary placement area 22e, an area in which multiple reels 70 can be temporarily placed is secured. Moving table 22b and attachment material 22c move above placement area 22d and temporary placement area 22e.

As illustrated in FIG. 2, tape loading mechanism 23 is provided near feeder holding section 21. Tape loading mechanism 23 loads carrier tape 72 in feeder 60 so that carrier tape 72 can be fed. For example, an articulated robot can be used as tape loading mechanism 23. Tape loading mechanism 23 of the embodiment includes articulated arm 23a, camera 23b, and multiple fingers 23c.

Articulated arm 23a can perform operations such as rotation and bending of the arm, and can adjust the positions and directions of camera 23b and multiple fingers 23c. Camera 23b is provided at a tip end portion of articulated arm 23a. Camera 23b captures an image of feeder 60 at the work execution position to detect the position and the state of reel 70 and carrier tape 72. Multiple fingers 23c are provided side by side with camera 23b at the tip end portion of articulated arm 23a. Multiple fingers 23c can perform a moving operation, a twisting operation, and the like in addition to the operation of gripping and releasing a work target.

Multiple fingers 23c loads carrier tape 72 so that feed hole 72e at a tip end portion of carrier tape 72 engages with sprocket 64, and sets carrier tape 72 in a feedable state. Multiple fingers 23c facilitate the loading operation of carrier tape 72 by rotating reel 70 around reel holding shaft 61 as necessary. Tape loading mechanism 23 takes a retracted posture in which articulated arm 23a is bent not to hinder the attaching and detaching operation of reel 70 in a time period other than the operation time.

Reel detachment mechanism 24 is provided on the first end side (arrow X1 direction) in the first direction of feeder holding section 21, and is disposed above reel attachment mechanism 22. Reel detachment mechanism 24 detaches reel 70 from feeder 60 at the work execution position. Reel detachment mechanism 24 includes guide rail 24a, moving table 24b, detachment material 24c, and retrieval box 24d.

Guide rail 24a is provided in the vicinity of the ceiling of first housing 11, and is formed to extend along the second direction (arrow Y direction). Moving table 24b is formed to extend along the first direction (arrow X direction), and is provided below guide rail 24a. As illustrated in FIGS. 1 and 2, moving table 24b moves along guide rail 24a and reciprocates between feeder holding section 21 and a standby position provided on the second end side (arrow Y2 direction) in the second direction.

Detachment material 24c is formed of a thick plate-shaped member longer than moving table 24b, and is provided to extend along the first direction (arrow X direction) below moving table 24b. Detachment material 24c swings (arrow SW2 in FIG. 1) between a horizontal posture illustrated in FIGS. 1 and 2 and a vertical posture in which detachment material 24c is tilted downward around swing shaft 24c1 provided on the second end side (arrow X2 direction) in the first direction of moving table 24b. Collection section 24c2 is provided on an end portion on a side different from the end portion on swing shaft 24c1 side of detachment material 24c. Collection section 24c2 detachably collects reel 70. The method of collecting collection section 24c2 may be the same as or different from collection section 22c2 of reel attachment mechanism 22.

Retrieval box 24d is provided to be positioned below detachment material 24c when moving table 24b is moved to the standby position. Retrieval box 24d retrieves multiple detached reels 70. Retrieval box 24d is formed in a box shape opening upward. Accordingly, retrieval box 24d can retrieve reel 70 that falls when collection section 24c2 of detachment material 24c releases reel 70.

Reel supply section 30 includes reel holding section 31 that is detachably provided. Pair of guide plates 12a and 12a extending along the second direction (arrow Y direction) is provided on the first end side (arrow X1 direction) in the first direction and the second end side (arrow X2 direction) in the first direction of the upper surface of base 12. Reel holding section 31 is placed between pair of guide plates 12a and 12a of base 12. As illustrated in FIG. 2, surfaces of pair of guide plates 12a and 12a facing each other on the first end side (arrow Y1 direction) in the second direction are formed in a tapered shape, and a separation distance on the first end side (arrow Y1 direction) in the second direction is longer than that on the second end side (arrow Y2 direction) in the second direction. This facilitates the work of inserting reel holding section 31 toward base 12 from the first end side (arrow Y1 direction) in the second direction.

Reel holding section 31 stacks and holds multiple reels 70 in a horizontal posture. Reel 70 is not limited to an unused reel, and may be a reel in use in which carrier tape 72 has been used halfway. Reel holding section 31 includes circular plate-shaped holding plate 31a provided horizontally, and round rod-shaped holding shaft 31b provided upward from the center of holding plate 31a and penetrating through the center hole of reel 70. Accordingly, reel holding section 31 can hold multiple reels 70 in a state where holding shaft 31b penetrates through the center holes of multiple reels 70 even when reels 70 having at least one of different diameter and different width dimension coexist, and reels 70 can be easily taken out. Identification code 31c is given to an upper surface of holding plate 31a. Identification code 31c includes information for specifying reel holding section 31.

For example, the worker procures multiple reels 70 based on work instruction data, and performs a stacking work of stacking multiple reels 70 on reel holding section 31. The work instruction data indicates a work content of the setup work performed by setup device 10. That is, in the work instruction data, type information of multiple reels 70 required with the progress of the production of the board product by the component mounter is associated with type information of multiple feeders 60 applicable to reels 70. A known automated guided vehicle or the like may also be used to convey multiple reels 70.

Reel transfer mechanism 40 is provided on plate base 12b extending from a bottom portion of base 12 to a second end side (arrow X2 direction) in the first direction. Reel transfer mechanism 40 includes support column 41, arm 42, and collection section 43. Support column 41 stands upward in the vertical direction on the second end side (arrow Y2 direction) in the second direction of plate base 12b. Arm 42 is provided to be liftable and lowerable with respect to support column 41. Further, arm 42 is provided to be rotatable on a horizontal plane around rotation shaft 44 close to support column 41.

Collection section 43 is provided to be extendable and contractible with respect to arm 42. Collection section 43 detachably collects reel 70. The method of collecting collection section 43 may be the same as or different from the method of collecting collection section 22c2 of reel attachment mechanism 22 and collection section 24c2 of reel detachment mechanism 24. Collection section 43 is provided with a code reader. The code reader reads identification code 31c of reel holding section 31. Further, the code reader can read the identification code of uppermost reel 70.

Reel transfer mechanism 40 functions as a part of reel attachment mechanism 22. Specifically, reel transfer mechanism 40 takes out reel 70 from reel holding section 31 by driving arm 42 and collection section 43. Further, reel transfer mechanism 40 places taken out reel 70 in placement area 22d or temporary placement area 22e in the state of the horizontal posture by driving arm 42 and collection section 43. Reel transfer mechanism 40 subsequently uses multiple reels 70 stacked on reel holding section 31 from the uppermost.

Feeder supply section 50 includes feeder accommodation section 51 that is detachably provided and feeder conveyance section 52. As illustrated in FIG. 2, storage space 13a in the upper portion of second housing 13 is open on the first end side (arrow Y1 direction) in the second direction, and can store multiple (for example, two in FIG. 2) feeder accommodation sections 51 arranged along the first direction (arrow X direction). As illustrated in FIG. 1, multiple roller conveyors 13b extending along the first direction (arrow X direction) are provided on a bottom surface defining storage space 13a, so that a storage operation of feeder accommodation section 51 is facilitated.

Feeder accommodation section 51 is formed in a box shape whose first end side (arrow Y1 direction) in the second direction is opened. Multiple slots having the same shape as slot 21b of feeder holding section 21 are formed on the bottom surface of feeder accommodation section 51. Feeder accommodation section 51 can accommodate multiple feeders 60 in a vertical posture arranged along the first direction (arrow X direction). When multiple feeders 60 are accommodated in feeder accommodation section 51 and feeder accommodation section 51 is properly stored in storage space 13a, the connectors of feeder 60 and feeder accommodation section 51 are fitted to each other, and multiple feeder control sections are communicably connected to setup device 10.

An identification code for identifying feeder accommodation section 51 is given to feeder accommodation section 51. For example, the worker procures multiple feeders 60 to be used based on the work instruction data, and performs the accommodation work of accommodating feeders 60 in feeder accommodation section 51. The number of feeder accommodation sections 51 that can be accommodated in storage space 13a may be one or three or more. A known automated guided vehicle or the like can also be used to convey multiple feeders 60.

Guide rail 13c is provided in a lower portion on the first end side (arrow Y1 direction) in the second direction of storage space 13a of second housing 13. Guide rail 13c is provided in storage space 13a over substantially the entire first direction (arrow X direction), and is provided to extend to the first end side (arrow Y1 direction) in the second direction of feeder holding section 21. Guide rail 13c is provided with feeder conveyance section 52. Feeder conveyance section 52 moves along guide rail 13c and reciprocates between feeder accommodation section 51 and feeder holding section 21.

Feeder conveyance section 52 is formed in a box shape having an opening portion on the second end side (arrow Y2 direction) in the second direction. Feeder conveyance section 52 includes a built-in space that temporarily incorporates feeder 60, and a feeder operation mechanism that conveys feeder 60 into the built-in space through the opening portion and conveys feeder 60 out of the built-in space. Accordingly, feeder conveyance section 52 can convey feeder 60 out of feeder accommodation section 51 and feeder holding section 21, and can convey feeder 60 into feeder accommodation section 51 and feeder holding section 21. An openable and closable safety fence is provided on the first end side (arrow Y1 direction) in the second direction of reel supply section 30 and feeder supply section 50, and the approach of the worker to reel supply section 30 and feeder supply section 50 is suppressed.

### 1-2. Control Example of Setup Device 10

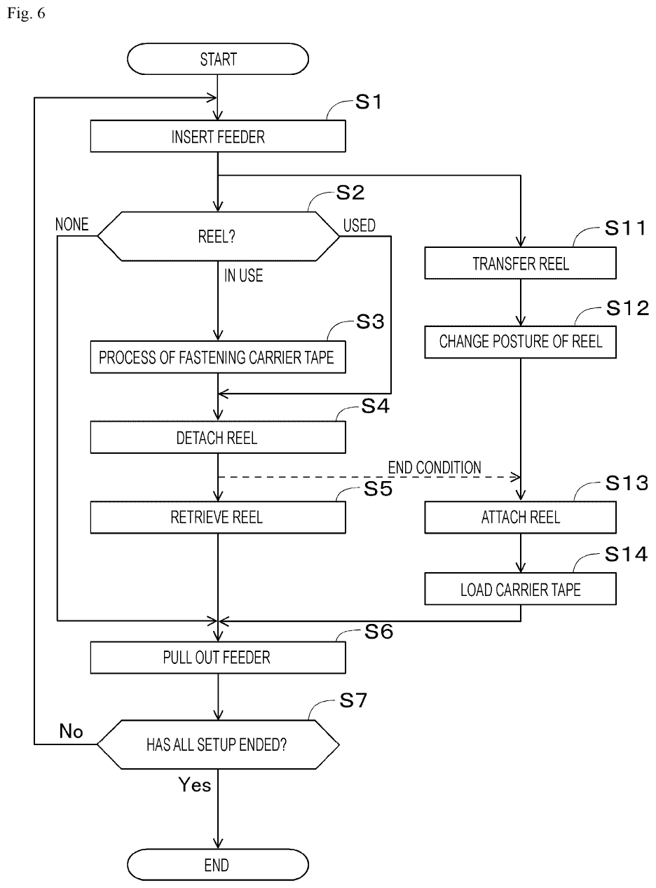

Setup device 10 causes feeder conveyance section 52 to convey feeder 60 corresponding to uppermost reel 70 of reel holding section 31 (step S1 illustrated in FIG. 6). Feeder conveyance section 52 pulls out and incorporates feeder 60 from feeder accommodation section 51, moves to feeder holding section 21, and inserts incorporated feeder 60 into feeder holding section 21. Accordingly, feeder 60 is held at the work execution position, and the identification code of feeder 60 is read.

When there is no feeder 60 applicable to uppermost reel 70 of reel holding section 31, reel 70 is placed in temporary placement area 22e by reel transfer mechanism 40. The above-described placement is repeated until applicable feeder 60 is present, and feeder 60 corresponding to uppermost reel 70 of reel holding section 31 is inserted into feeder holding section 21. After the control illustrated in step S1, in setup device 10, a first-series control illustrated in steps S2 to S5 and a second-series control illustrated in steps S11 to S14 are executed in parallel.

In the first-series control, setup device 10 checks the state of reel 70 based on the read identification code of feeder 60 or the read identification code of reel 70, and changes the control according to the state of reel 70 (step S2). Specifically, when feeder 60 is used in the component mounter in advance, there is a possibility that reel 70 in use in which carrier tape 72 has been used halfway is provided in feeder 60. In this case, tape loading mechanism 23 performs a fastening process of fixing the tip end portion of carrier tape 72 with a tape or the like to suppress slack of carrier tape 72 (step S3). At this time, tape loading mechanism 23 can wind carrier tape 72 around reel 70 as necessary. Thereafter, tape loading mechanism 23 takes a retracted posture in which articulated arm 23a is bent.

Next, reel detachment mechanism 24 detaches reel 70 from feeder 60 (step S4). Specifically, moving table 24b moves from the standby position to feeder holding section 21. Then, when detachment material 24c is swung from the horizontal posture to the vertical posture, collection section 24c2 comes into contact with reel 70 and collects reel 70. Then, when detachment material 24c returns from the vertical posture to the horizontal posture, collection section 24c2 pulls out reel 70 from reel holding shaft 61 and holds reel 70 in the horizontal posture. At this time, setup device 10 deletes the identification code of reel 70 from the storage section of the feeder control section of feeder 60. Further, setup device 10 transmits the identification code of feeder 60, from which reel 70 has been detached, to a higher-level management device. At this time, setup device 10 may transmit the identification code of detached reel 70 together with the identification code of feeder 60 to the higher-level management device.

Next, reel detachment mechanism 24 retrieves reel 70 (step S5). Specifically, first, moving table 24b moves from feeder holding section 21 to the standby position. Then, collection section 24c2 releases reel 70. Thus, released reel 70 falls into retrieval box 24d and is retrieved. When reel 70 is retrieved, the first-series control is in a standby state until the second-series control ends.

There is a possibility that feeder 60 is provided with used reel 70 in which all of carrier tape 72 has been used (step S2). In this case, in the first-series control, the control illustrated in step S3 is omitted, and the controls illustrated in step S4 and step S5 are executed. There is a possibility that feeder 60 is not provided with reel 70 (step S2). In this case, in the first-series control, the controls illustrated in steps S3 to S5 are omitted.

In the second-series control, reel transfer mechanism 40 collects uppermost reel 70 of reel holding section 31 using collection section 43, and places reel 70 in placement area 22d (step S11). Then, reel transfer mechanism 40 returns collection section 43 to above reel holding section 31. When there is no applicable feeder 60, reel transfer mechanism 40 places reel 70 in temporary placement area 22e.

Next, reel attachment mechanism 22 changes the posture of reel 70 in placement area 22d (step S12). Specifically, first, attachment material 22c is changed from the upright posture to the horizontal posture, and collection section 22c2 comes into contact with reel 70 to collect reel 70. Then, attachment material 22c is returned from the horizontal posture to the upright posture, and collection section 22c2 changes reel 70 from the horizontal posture to the vertical posture and holds reel 70. When reel 70 in temporary placement area 22e is used, moving table 22b moves to the second end side (arrow X2 direction) in the first direction by a predetermined distance before attachment material 22c shifts from the upright posture to the horizontal posture. The second-series control is in a standby state until an end condition indicating the completion of the control of step S4 of the first series is satisfied. This avoids interference between reel attachment mechanism 22 and reel detachment mechanism 24.

When the end condition described above is satisfied, reel attachment mechanism 22 attaches reel 70 on feeder 60 (step S13). Specifically, in a state where collection section 22c2 holds reel 70 in the vertical posture, moving table 22b moves to feeder holding section 21. Accordingly, reel 70 moves toward reel holding shaft 61 and is attached to reel holding shaft 61. The movement of moving table 22b can be performed simultaneously with the movement of moving table 24b to the standby position.

When the attachment of reel 70 ends, setup device 10 stores the identification code of reel 70 in the feeder control section of feeder 60 to which reel 70 is attached. Further, setup device 10 transmits the identification code of feeder 60 and the identification code of reel 70 mounted on feeder 60 to the higher-level management device in association with each other. Moving table 22b returns to the standby position. Next, tape loading mechanism 23 loads carrier tape 72 until feed hole 72e of carrier tape 72 engages with the teeth portion of sprocket 64 (step S14).

When the first-series control and the second-series control end, feeder conveyance section 52 pulls out feeder 60 from feeder holding section 21, incorporates feeder 60 therein, moves feeder 60 to feeder accommodation section 51, and inserts incorporated feeder 60 into feeder accommodation section 51 (step S6). Thus, the setup work for one feeder 60 ends. Setup device 10 determines whether the setup work for all feeders 60 has ended (step S7). When the setup work for all feeders 60 has ended (Yes in step S7), the control by setup device 10 temporarily ends. When the setup work for all feeders 60 has not ended (No in step S7), the control by setup device 10 returns to the control illustrated in Step S1, and the control described above is repeated until the setup work for all feeders 60 ends.

When the control by setup device 10 ends, for example, the worker conveys feeder accommodation section 51 accommodating feeders 60 that have been set up to the component mounter, and performs the setup change of feeders 60. When reel 70 is placed in temporary placement area 22e, reel 70 becomes usable when the worker accommodates feeder 60 applicable to reel 70 in feeder accommodation section 51. Further, reel 70 left unused in temporary placement area 22e is returned to reel holding section 31 by reel transfer mechanism 40 and retrieved by the worker. Further, the above-described conveyance work by the worker can also be automated using a known automated guided vehicle or the like.

### 1-3. Configuration Example of Tape Releasing Device 80

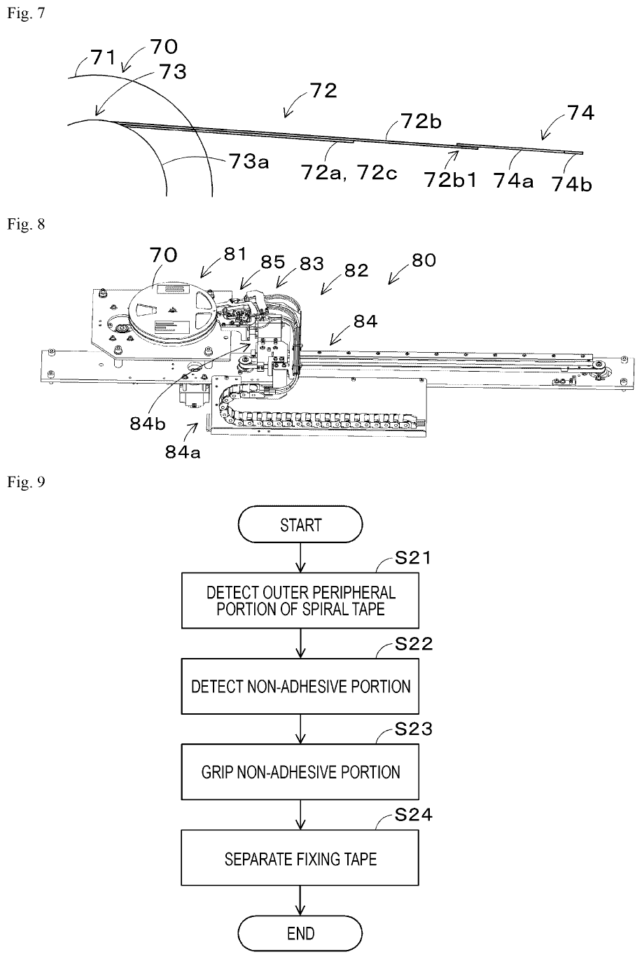

As illustrated in FIG. 3, carrier tape 72 is spirally wound around reel 70. As illustrated in FIG. 7, for example, the tip end side of carrier tape 72 of unused reel 70 is formed such that cover tape 72b protrudes from base tape 72a. Tip end portion 72b1 of cover tape 72b and outer peripheral portion 73a of spiral tape 73 are fixed by fixing tape 74.

FIG. 7 is a schematic view of reel 70 as viewed in the rotation axis direction, and illustrates a state, in which fixing tape 74 has been released from outer peripheral portion 73a of spiral tape 73 and the tip end side of carrier tape 72 is extended, for convenience of description. As described above, with respect to reel 70 in use, a process of fastening carrier tape 72 is performed. In this case, similarly to unused reel 70, the tip end side of carrier tape 72 can be fixed by fixing tape 74.

As described above, when reel 70 in which the tip end side of carrier tape 72 is fixed by fixing tape 74 is set in feeder 60, it is necessary to release fixing tape 74. When a worker performs the release of fixing tape 74, the number of work steps of the worker increases. Here, in the embodiment, tape releasing device 80 is provided. Tape releasing device 80 releases fixing tape 74 of reel 70.

Specifically, tape releasing device 80 includes reel support section 81 and release section 82. Release section 82 may include gripping mechanism 83. Release section 82 may also include separation mechanism 84. Tape releasing device 80 may also include detection section 85. As illustrated in FIG. 8, tape releasing device 80 of the embodiment includes reel support section 81, release section 82, and detection section 85. Release section 82 includes gripping mechanism 83 and separation mechanism 84. Tape releasing device 80 of the embodiment executes control according to the flowchart illustrated in FIG. 9.

### 1-3-1. Reel Support Section 81

Reel support section 81 supports reel 70 on which outer peripheral portion 73a of spiral tape 73, on which carrier tape 72 is spirally wound, and tip end portion 72b1 of cover tape 72b are fixed by first fixing tape 74. As described above, in carrier tape 72, cover tape 72b that closes accommodation section 72d is attached to base tape 72a provided with accommodation section 72d that accommodates electronic component 91.

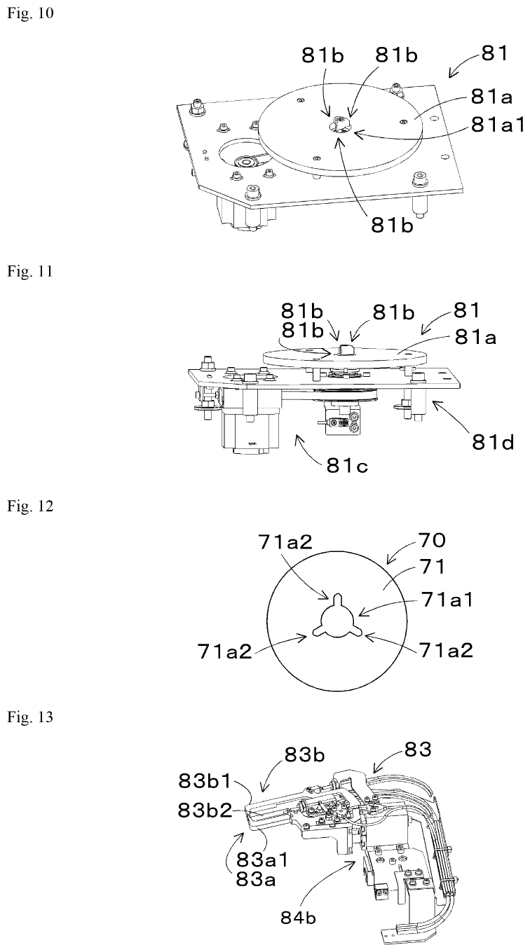

Reel support section 81 need only store reel 70 described above, and may take various configurations. For example, reel support section 81 rotatably supports reel 70. As illustrated in FIGS. 10 and 11, reel support section 81 includes placement section 81a, multiple (for example, three) claw portions 81b, drive section 81c, and reel detection section 81d. Placement section 81a is formed in a circular plate shape equivalent to the diameter of reel 70, and reel 70 described above is placed.

Placement section side hole portion 81a1 is formed in the center of placement section 81a such that multiple (three) claw portions 81b can protrude. Placement section side hole portion 81a1 is formed to be slightly larger than reel side hole portion 71a1 formed in the center of main body portion 71 of reel 70. As illustrated in FIG. 12, multiple (for example, three) groove portions 71a2 extending radially from the rotation axis (the center of main body portion 71) of reel 70 are formed in reel side hole portion 71a1.

Multiple (three) groove portions 71a2 are disposed at equal intervals (in this case, at positions rotated by 120° each) as viewed in the rotation axis direction of reel 70. Multiple (three) claw portions 81b are provided in accordance with the disposition of multiple (three) groove portions 71a2. Accordingly, when reel 70 is placed on placement section 81a, multiple (three) claw portions 81b can be fitted to multiple (three) groove portions 71a2.

Multiple (three) claw portions 81b are connected to the drive shaft of drive section 81c. Drive section 81c need only rotate the drive shaft, and may take various configurations. In the embodiment, a known belt driving device is used for drive section 81c. Drive section 81c rotates multiple (three) claw portions 81b connected to the drive shaft by rotating the drive shaft. When multiple (three) claw portions 81b rotate, reel 70 placed on placement section 81a rotates.

Reel detection section 81d detects whether reel 70 is appropriately placed on placement section 81a. When reel 70 is appropriately placed on placement section 81a, multiple (three) claw portions 81b are fitted to multiple (three) groove portions 71a2. Conversely, when reel 70 is not appropriately placed on placement section 81a, the fitting described above is not sufficient, and reel 70 is lifted from placement section 81a. Reel detection section 81d can detect the lifting described above.

In the embodiment, reel detection section 81d includes a detection device positioned at a predetermined distance above from the height position of reel 70 that is appropriately placed on placement section 81a. For example, the detection device emits detection light in the horizontal direction toward the upper side of reel 70. When reel 70 is appropriately placed on placement section 81a, the detection light is not blocked, and reel detection section 81d detects that reel 70 is appropriately placed on placement section 81a (there is no lifting described above). Conversely, when reel 70 is not appropriately placed on placement section 81a, the detection light is blocked, and reel detection section 81d detects that reel 70 is not appropriately placed on placement section 81a (there is the lifting described above). Reel detection section 81d can also check the front and back of reel 70 by reading the identification code attached to reel 70.

### 1-3-2. Release Section 82, Gripping Mechanism 83, Separation Mechanism 84, and Detection Section 85

Release section 82 releases fixing tape 74 of reel 70 supported by reel support section 81. Release section 82 need only release fixing tape 74, and may take various configurations. In the embodiment, release section 82 includes gripping mechanism 83 and separation mechanism 84. Tape releasing device 80 includes detection section 85. Tape releasing device 80 can assume any combination of reel support section 81, release section 82 (gripping mechanism 83 and separation mechanism 84), and detection section 85, and the details described in the present description herein can be applied as appropriate.

When an adhesive is provided over the entire surface of fixing tape 74 on the side fixed to outer peripheral portion 73a of spiral tape 73, it is difficult to release fixing tape 74. Therefore, as illustrated in FIG. 7, fixing tape 74 includes adhesive portion 74a and non-adhesive portion 74b. Adhesive portion 74a is a portion where an adhesive is provided. The adhesive is provided on a portion on the base end side of fixing tape 74 on the surface of fixing tape 74 on the side fixed to outer peripheral portion 73a of spiral tape 73.

Adhesive portion 74a fixes tip end portion 72b1 of cover tape 72b and fixing tape 74. Adhesive portion 74a fixes outer peripheral portion 73a of spiral tape 73 and fixing tape 74. Non-adhesive portion 74b is a portion on the tip end side of fixing tape 74, and is a portion where the adhesive for fixing tape 74 and outer peripheral portion 73a of spiral tape 73 is not provided. Since non-adhesive portion 74b is not provided with an adhesive on the surface of fixing tape 74, which is on a side to be fixed to outer peripheral portion 73a of spiral tape 73, non-adhesive portion 74b is not fixed to outer peripheral portion 73a of spiral tape 73 and is thus grippable.

Here, gripping mechanism 83 grips non-adhesive portion 74b. Gripping mechanism 83 need only grip non-adhesive portion 74b, and may take various configurations. In the embodiment, as illustrated in FIGS. 13 to 18, gripping mechanism 83 includes first gripping mechanism 83a and second gripping mechanism 83b. First gripping mechanism 83a includes first claw portion 83al that is insertable between outer peripheral portion 73a of spiral tape 73 and non-adhesive portion 74b. Second gripping mechanism 83b grips non-adhesive portion 74b in cooperation with first gripping mechanism 83a.

Second gripping mechanism 83b need only grip non-adhesive portion 74b in cooperation with first gripping mechanism 83a, and may take various configurations. For example, second gripping mechanism 83b may include second claw portion 83b1. Second claw portion 83b1 grips non-adhesive portion 74b in cooperation with first claw portion 83a1 in a state where first claw portion 83a1 is inserted between outer peripheral portion 73a of spiral tape 73 and non-adhesive portion 74b. Specifically, the tip end portion of first claw portion 83a1 and the tip end portion of second claw portion 83b1 protrude in opposing directions, and non-adhesive portion 74b is gripped between the tip end portion of first claw portion 83a1 and the tip end portion of second claw portion 83b1, so that non-adhesive portion 74b is gripped.

The embodiment described above is suitable for a case where fixing tape 74 is made of a material that is relatively difficult to bend, such as a resin tape. Fixing tape 74 includes a tape made of a material that is relatively easy to bend, such as a paper tape. In this case, non-adhesive portion 74b of fixing tape 74 may lift up, making it difficult for first claw portion 83a1 and second claw portion 83b1 to grip non-adhesive portion 74b. Therefore, second gripping mechanism 83b may include second claw portion 83b1 and pressing section 83b2.

In the embodiment described above, second claw portion 83b1 places non-adhesive portion 74b on first claw portion 83a1 in a state where first claw portion 83a1 is inserted between outer peripheral portion 73a of spiral tape 73 and non-adhesive portion 74b. Pressing section 83b2 presses non-adhesive portion 74b in a state where non-adhesive portion 74b is placed on first claw portion 83a1 by second claw portion 83b1. Pressing section 83b2 need only press non-adhesive portion 74b, and may take various configurations. In the embodiment, pressing section 83b2 is formed in a rod shape. In this embodiment, non-adhesive portion 74b is gripped by first claw portion 83a1 and pressing section 83b2.

Detection section 85 detects non-adhesive portion 74b. Detection section 85 need only detect non-adhesive portion 74b, and may take various configurations. For example, when the same number of electronic components 91 are accommodated in reel 70, the diameter of spiral tape 73 varies depending on the thickness of electronic components 91. Specifically, as the thickness of electronic component 91 increases, the diameter of spiral tape 73 increases. When the diameter of spiral tape 73 varies, the distance from gripping mechanism 83 to outer peripheral portion 73a of spiral tape 73 in which non-adhesive portion 74b is present also varies. Therefore, it is preferable for detection section 85 to include outer peripheral detection section 85s that detects outer peripheral portion 73a of spiral tape 73. In this case, detection section 85 can detect non-adhesive portion 74b with reference to outer peripheral portion 73a of spiral tape 73 detected by outer peripheral detection section 85s.

For example, outer peripheral detection section 85s detects outer peripheral portion 73a of spiral tape 73 by bringing gripping mechanism 83 capable of gripping non-adhesive portion 74b into contact with outer peripheral portion 73a of spiral tape 73 (step S21 illustrated in FIG. 9). Then, detection section 85 detects non-adhesive portion 74b by relatively moving gripping mechanism 83 along outer peripheral portion 73a of spiral tape 73 detected by outer peripheral detection section 85s (step S22). As illustrated in FIGS. 13 to 18, in the embodiment, gripping mechanism 83 includes first claw portion 83a1. Outer peripheral detection section 85s includes first dog 85a and first sensor 85b.

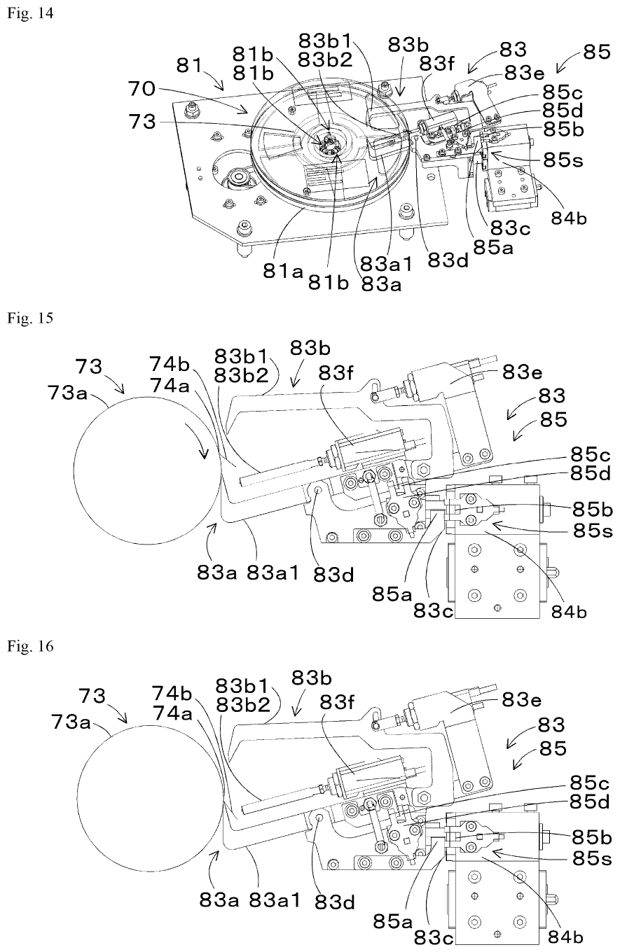

First dog 85a is displaced when first claw portion 83a1 moves toward outer peripheral portion 73a of spiral tape 73 and reaches outer peripheral portion 73a of spiral tape 73. First sensor 85b detects that first claw portion 83a1 has reached outer peripheral portion 73a of spiral tape 73 by the displacement of first dog 85a. For example, outer peripheral detection section 85s moves gripping mechanism 83 toward reel 70 by using drive section 84a of separation mechanism 84 illustrated in FIG. 8. As illustrated in FIGS. 14 and 15, gripping mechanism 83 is supported by moving body 84b of separation mechanism 84 via elastic member 83c. Elastic member 83c is formed by, for example, a spring.

When gripping mechanism 83 moves toward outer peripheral portion 73a of spiral tape 73 together with moving body 84b, gripping mechanism 83 reaches outer peripheral portion 73a of spiral tape 73, and moving body 84b further moves, gripping mechanism 83 relatively displaces with respect to moving body 84b. More specifically, when moving body 84b further moves toward spiral tape 73 after first claw portion 83a1 has reached outer peripheral portion 73a of spiral tape 73, elastic member 83c contracts against the elastic force, and gripping mechanism 83 relatively displaces with respect to moving body 84b. When elastic member 83c contracts, first dog 85a provided in gripping mechanism 83 moves toward first sensor 85b provided in moving body 84b and blocks the detection light of first sensor 85b. Thus, outer peripheral detection section 85s detects that first claw portion 83a1 has reached outer peripheral portion 73a of spiral tape 73.

As described above, detection section 85 includes first dog 85a and first sensor 85b. Detection section 85 includes second dog 85c and second sensor 85d. Second dog 85c is displaced when, in a state where first claw portion 83al has reached outer peripheral portion 73a of spiral tape 73, reel 70 is rotated by reel support section 81 so that first claw portion 83a1 is inserted between outer peripheral portion 73a of spiral tape 73 and non-adhesive portion 74b, and reaches adhesive portion 74a. Second sensor 85d detects that first claw portion 83al has reached adhesive portion 74a of fixing tape 74 by the displacement of second dog 85c.

Specifically, in the state illustrated in FIG. 15, when reel 70 is rotated by reel support section 81, the state illustrated in FIG. 16 is obtained. When reel 70 further rotates after first claw portion 83a1 has reached adhesive portion 74a, first claw portion 83a1 rotates counterclockwise around rotating section 83d in the plane view of FIG. 16. Due to the rotation of first claw portion 83a1, second dog 85c provided in first claw portion 83a1 moves away from second sensor 85d, and the detection light of second sensor 85d is no longer blocked. Thus, detection section 85 detects that first claw portion 83a1 has reached adhesive portion 74a of fixing tape 74, and detects non-adhesive portion 74b on the tip end side with respect to adhesive portion 74a.

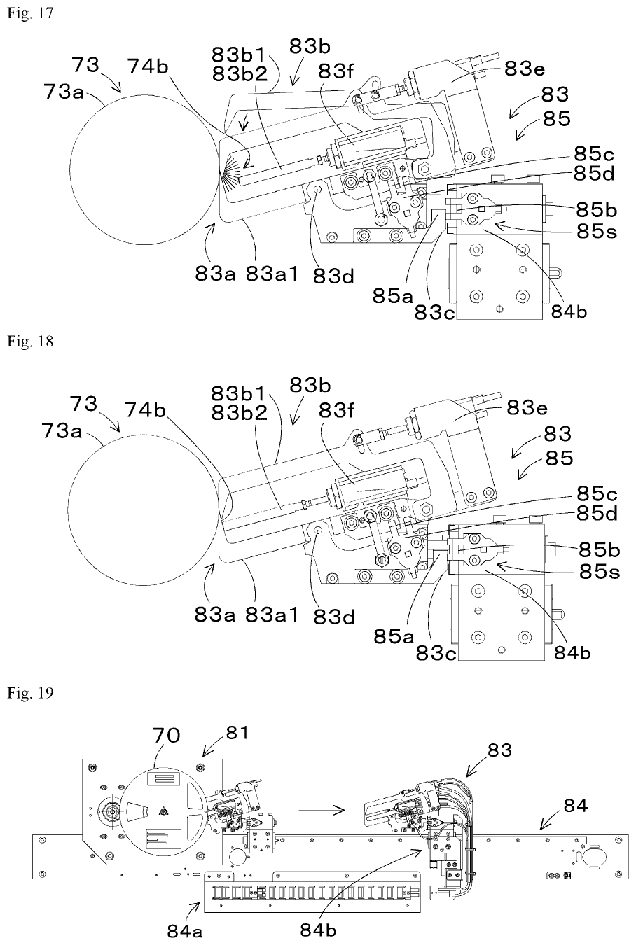

In the embodiment, first gripping mechanism 83a includes first claw portion 83a1. Second gripping mechanism 83b includes second gripping mechanism 83b and pressing section 83b2. Gripping mechanism 83 grips non-adhesive portion 74b using first claw portion 83a1, second claw portion 83b1, and pressing section 83b2 (step S23 illustrated in FIG. 9). As illustrated in FIG. 17, second gripping mechanism 83b uses second claw portion 83b1 to place non-adhesive portion 74b on first claw portion 83a1 in a state where first claw portion 83a1 is inserted between outer peripheral portion 73a of spiral tape 73 and non-adhesive portion 74b. Specifically, second gripping mechanism 83b, for example, uses linear motion mechanism 83e, such as a cylinder, to push out and rotate second claw portion 83b1. Thus, non-adhesive portion 74b is placed on first claw portion 83a1.

Next, as illustrated in FIG. 18, second gripping mechanism 83b presses non-adhesive portion 74b using pressing section 83b2 in a state where non-adhesive portion 74b is placed on first claw portion 83a1 by second claw portion 83b1. Specifically, second gripping mechanism 83b, for example, uses linear motion mechanism 83f, such as a cylinder, to push pressing section 83b2. Thus, non-adhesive portion 74b is gripped by first claw portion 83a1 and pressing section 83b2.

Separation mechanism 84 separates fixing tape 74 from cover tape 72b (step S24 illustrated in FIG. 9). Separation mechanism 84 need only separate fixing tape 74 from cover tape 72b, and may take various configurations. As illustrated in FIG. 19, in the embodiment, separation mechanism 84 moves gripping mechanism 83 in a direction away from reel 70 in a state where gripping mechanism 83 grips non-adhesive portion 74b, and separates fixing tape 74 from cover tape 72b.

Specifically, separation mechanism 84 includes drive section 84a. Drive section 84a need only move gripping mechanism 83 as described above, and may take various configurations. In the embodiment, a known belt driving device is used as drive section 84a. Drive section 84a can move gripping mechanism 83 in a direction away from reel 70 (right direction in the plane view of FIG. 19). Drive section 84a can also move gripping mechanism 83 in a direction toward reel 70 (left direction in the plane view of FIG. 19).

Reel support section 81 rotatably supports reel 70. When reel 70 is placed on placement section 81a, multiple (three) claw portions 81b are fitted to multiple (three) groove portions 71a2. In addition, multiple (three) claw portions 81b are connected to the drive shaft of drive section 81c. Therefore, when separation mechanism 84 moves gripping mechanism 83, resistance may occur in the rotation of reel 70. As the resistance increases, carrier tape 72 is more likely to be broken when gripping mechanism 83 moves.

Reel support section 81 may set the rotation amount of reel 70 in accordance with the movement amount of gripping mechanism 83 so that carrier tape 72 does not break when gripping mechanism 83 moves. For example, in the embodiment, gripping mechanism 83 includes first claw portion 83a1. Tape releasing device 80 includes first dog 85a and first sensor 85b. In this case, reel support section 81 estimates the diameter of spiral tape 73 based on the position of first claw portion 83a1 when first sensor 85b detects that first claw portion 83a1 has reached outer peripheral portion 73a of spiral tape 73, and sets the rotation amount of reel 70 based on the estimated diameter of spiral tape 73.

Specifically, drive section 84a of separation mechanism 84 includes, for example, a position detector such as an encoder. The position detector can detect the distance between the center position of reel 70 supported by reel support section 81 and the position of first claw portion 83a1 when first sensor 85b detects that first claw portion 83a1 has reached outer peripheral portion 73a of spiral tape 73. The distance corresponds to the radius of spiral tape 73. Accordingly, reel support section 81 can estimate the diameter of spiral tape 73 based on the distance detected by the position detector.

Reel support section 81 sets the rotation amount of reel 70 based on the estimated diameter of spiral tape 73. Specifically, reel support section 81 calculates the length (circumference) of outer peripheral portion 73a of spiral tape 73 from the diameter of spiral tape 73. The length of outer peripheral portion 73a is a value obtained by multiplying the diameter of spiral tape 73 by pi. Accordingly, reel support section 81 can recognize the pulled-out amount of carrier tape 72 per unit rotation amount of reel 70. Reel support section 81 acquires the pulled-out amount of carrier tape 72 from the movement amount of gripping mechanism 83, and sets the rotation amount of reel 70 in accordance with the pulled-out amount of carrier tape 72. When the drive shaft of drive section 81c of reel support section 81 can be separated, the drive shaft of drive section 81c may be separated.

### 2. Tape Releasing Device 80 and Tape Loading Device 100

Tape releasing device 80 can be provided at any position inside or outside setup device 10. For example, tape releasing device 80 can be provided near tape loading mechanism 23 and reel transfer mechanism 40 (for example, placement area 22d, or the like). Placement of reel 70 on placement section 81a of reel support section 81 may be performed by the worker or may be performed by reel transfer mechanism 40, or the like. Further, reel 70 from which fixing tape 74 has been released by tape releasing device 80 may be attached to feeder 60 by the worker, or may be attached to feeder 60 by tape loading device 100.

Tape loading device 100 includes tape releasing device 80 and loading section 90. Tape releasing device 80 may take any of the configurations described above. Loading section 90 loads carrier tape 72 of spiral tape 73, from which fixing tape 74 has been released, into feeder 60 that supplies electronic component 91 to collection position 63. Loading section 90 corresponds to tape loading mechanism 23. That is, loading section 90 may include articulated arm 23a, camera 23b, and fingers 23c.

For example, loading section 90 can load carrier tape 72 into feeder 60 by gripping the tip end portion of carrier tape 72, which has been pulled out from spiral tape 73, from which fixing tape 74 has been released, by fingers 23c. Reel attachment mechanism 22 can change reel 70, from which fixing tape 74 has been released, from the horizontal posture to the vertical posture, and attach reel 70 to feeder 60 at the work execution position. Tape loading device 100 may include various configurations described above for setup device 10.

### 3. Modification Example

Detection section 85 need only detect non-adhesive portion 74b, and may take various configurations. For example, detection section 85 of the embodiment includes outer peripheral detection section 85s, and outer peripheral detection section 85s is a contact-type detection section that detects outer peripheral portion 73a of spiral tape 73 by bringing gripping mechanism 83 capable of gripping non-adhesive portion 74b into contact with outer peripheral portion 73a of spiral tape 73. However, detection section 85 may be a non-contact type detection section that detects non-adhesive portion 74b without bringing gripping mechanism 83 into contact with outer peripheral portion 73a of spiral tape 73. For example, detection section 85 may capture an image of outer peripheral portion 73a of spiral tape 73 using the imaging device and detect non-adhesive portion 74b based on the captured image. Outer peripheral detection section 85s can also detect outer peripheral portion 73a of spiral tape 73 using a non-contact type range sensor such as a laser displacement meter.

### 4. Example of Advantageous Effects of Embodiment

With tape releasing device 80, fixing tape 74 of reel 70 can be released. Tape loading device 100 also includes tape releasing device 80. Therefore, what has been described above with respect to tape releasing device 80 can be said to be the same for tape loading device 100.

### Reference Signs List

60: feeder, 63: collection position, 70: reel, 72: carrier tape, 72a: base tape, 72b: cover tape, 72b1: tip end portion, 72d: accommodation section, 73: spiral tape, 73a: outer peripheral portion, 74: fixing tape, 74a: adhesive portion, 74b: non-adhesive portion, 80: tape releasing device, 81: reel support section, 82: release section, 83: gripping mechanism, 83a: first gripping mechanism, 83a1: first claw portion, 83b: second gripping mechanism, 83b1: second claw portion, 83b2: pressing section, 84: separation mechanism, 85: detection section, 85a: first dog, 85b: first sensor, 85c: second dog, 85d: second sensor, 85s: outer peripheral detection section, 90: loading section, 100: tape loading device, 91: electronic component.

1. A tape releasing device comprising:
a reel support section configured to support a reel in which an outer peripheral portion of a spiral tape, where a carrier tape, in which a cover tape that closes an accommodation section that accommodates an electronic component is attached to a base tape provided with the accommodation section, is spirally wound, and a tip end portion of the cover tape are fixed by a fixing tape; and
a release section configured to release the fixing tape of the reel supported by the reel support section.

2. The tape releasing device according to claim 1,
wherein the release section includes a gripping mechanism capable of gripping a non-adhesive portion that is a portion on a tip end side of the fixing tape, the non-adhesive portion being where an adhesive that fixes the fixing tape and the outer peripheral portion of the spiral tape is not provided.

3. The tape releasing device according to claim 2,
wherein the gripping mechanism includes:
a first gripping mechanism including a first claw portion that is insertable between the outer peripheral portion of the spiral tape and the non-adhesive portion; and
a second gripping mechanism configured to grip the non-adhesive portion in cooperation with the first gripping mechanism.

4. The tape releasing device according to claim 3,
wherein the second gripping mechanism includes:
a second claw portion configured to place the non-adhesive portion on the first claw portion in a state where the first claw portion is inserted between the outer peripheral portion of the spiral tape and the non-adhesive portion; and
a pressing section configured to press the non-adhesive portion in a state where the non-adhesive portion is placed on the first claw portion by the second claw portion.

5. The tape releasing device according to claim 1, further comprising:
a detection section configured to detect a non-adhesive portion that is a portion on a tip end side of the fixing tape, the non-adhesive portion being where an adhesive that fixes the fixing tape and the outer peripheral portion of the spiral tape is not provided.

6. The tape releasing device according to claim 5,
wherein the detection section includes an outer peripheral detection section configured to detect the outer peripheral portion of the spiral tape, and detects the non-adhesive portion with reference to the outer peripheral portion of the spiral tape detected by the outer peripheral detection section.

7. The tape releasing device according to claim 6,
wherein the outer peripheral detection section detects the outer peripheral portion of the spiral tape by bringing a gripping mechanism capable of gripping the non-adhesive portion into contact with the outer peripheral portion of the spiral tape, and
the detection section detects the non-adhesive portion by relatively moving the gripping mechanism along the outer peripheral portion of the spiral tape detected by the outer peripheral detection section.

8. The tape releasing device according to claim 5,
wherein the reel support section rotatably supports the reel,
the release section includes a gripping mechanism including a first claw portion that is insertable between the outer peripheral portion of the spiral tape and the non-adhesive portion, and
the detection section includes:
a first dog which is displaced when the first claw portion moves toward the outer peripheral portion of the spiral tape and reaches the outer peripheral portion of the spiral tape;
a first sensor configured to detect that the first claw portion has reached the outer peripheral portion of the spiral tape by the displacement of the first dog;
a second dog which is displaced when, in a state where the first claw portion has reached the outer peripheral portion of the spiral tape, the reel is rotated by the reel support section so that the first claw portion is inserted between the outer peripheral portion of the spiral tape and the non-adhesive portion, and reaches an adhesive portion of the fixing tape where the adhesive is provided; and
a second sensor configured to detect that the first claw portion has reached the adhesive portion of the fixing tape by the displacement of the second dog.

9. The tape releasing device according to claim 1,
wherein the release section includes a separation mechanism configured to separate the fixing tape from the cover tape.

10. The tape releasing device according to claim 9,
wherein the release section includes a gripping mechanism capable of gripping a non-adhesive portion that is a portion on a tip end side of the fixing tape, the non-adhesive portion being where an adhesive that fixes the fixing tape and the outer peripheral portion of the spiral tape is not provided, and
the separation mechanism moves the gripping mechanism in a direction away from the reel in a state where the gripping mechanism grips the non-adhesive portion, and separates the fixing tape from the cover tape.

11. The tape releasing device according to claim 10,
wherein the reel support section rotatably supports the reel, and sets a rotation amount of the reel in accordance with a movement amount of the gripping mechanism so that the carrier tape does not break when the gripping mechanism moves.

12. The tape releasing device according to claim 11,
wherein the gripping mechanism includes a first claw portion that is insertable between the outer peripheral portion of the spiral tape and the non-adhesive portion,
the tape releasing device includes:
a first dog which is displaced when the first claw portion moves toward the outer peripheral portion of the spiral tape and reaches the outer peripheral portion of the spiral tape; and
a first sensor configured to detect that the first claw portion has reached the outer peripheral portion of the spiral tape by the displacement of the first dog, and
the reel support section estimates a diameter of the spiral tape based on a position of the first claw portion when the first sensor detects that the first claw portion has reached the outer peripheral portion of the spiral tape, and sets the rotation amount of the reel based on the estimated diameter of the spiral tape.

13. A tape loading device comprising:
the tape releasing device according to claim 1; and
a loading section configured to load the carrier tape of the spiral tape, from which the fixing tape has been released, to a feeder configured to supply the electronic component to a collection position.
